(19) United States
(12) Patent Application Publication
(10) Pub. No.: US 2010/0227107 A1
(43) Pub. Date: Sep. 9, 2010

(54) RECORDING LAYER FOR OPTICAL INFORMATION RECORDING MEDIUM, OPTICAL INFORMATION RECORDING MEDIUM, AND SPATTERING TARGET

(75) Inventors: Tatewaki Ido, Kobe-shi (JP); Hideo Fuji, Kobe-shi (JP); Yuki Tauchi, Kobe-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Kobe Seiko Sho (Kobe Steel Ltd.), Kobe-shi (JP)

(21) Appl. No.: 12/160,312

(22) PCT Filed: Feb. 1, 2007
(86) PCT No.: PCT/JP2007/051732

§ 371 Date: Jul. 9, 2008

(30) Foreign Application Priority Data
Feb. 3, 2006 (JP) 2006-027192
Jun. 13, 2006 (JP) 2006-163846

(51) Int. Cl. B32B 3/02; C23C 14/34

(52) U.S. Cl. 428/64.4; 204/298.13

(57) ABSTRACT

Disclosed are optical information recording layers to create recording marks upon irradiation with a laser beam, in which the recording layers are composed of: an indium alloy containing 0.1 to 15 atomic percent of one or more rare-earth elements; an indium alloy containing 0.1 to 50 atomic percent of one element selected from the group consisting of palladium (Pd), cobalt (Co), platinum (Pt), and vanadium (V); an indium alloy containing 6 to 50 atomic percent of nickel (Ni); or an indium alloy containing 0.1 or more and less than 50 atomic percent of gold (Au). Also disclosed are information storage media provided with the recording layers, and sputtering targets for the deposition of the recording layers, which have the alloy compositions.

### TECHNICAL FIELD

The present invention relates to recording layers for optical information storage media (optical recording layers); optical information storage media; and sputtering targets for the deposition of optical recording layers. The recording layers for optical information storage media according to the present invention can be used not only for current compact discs (CDs) and digital versatile discs (DVDs) but also for next-generation optical information storage media such as HD-DVDs and Blu-ray Discs, and particularly suitably used for write-once, high-density optical information storage media using blue-violet laser.

### BACKGROUND ART

Optical information storage media (optical discs) are roughly categorized by the writing and reading system into three main types, i.e., read-only, rewritable, and write-once optical discs.

Among these discs, write-once optical discs are configured to record data by principally utilizing changes in properties of materials in the recording layer upon irradiation with a laser beam. In these write-once optical discs, data can be recorded but neither erased nor rewritten. Using these properties, the write-once optical discs are widely used for storage of data, such as text files and image files, which will not be corrected or rewritten, and they are commercially available typically as CD-R, DVD-R, and DVD+R discs.

Materials for recording layers used for the write-once optical discs include organic dye materials such as cyanine dyes, phthalocyanine dyes, and azo dyes. When irradiated with a laser beam, an organic dye material absorbs heat, and the dye and/or a substrate decomposes, melts, and/or evaporates to thereby create a recording mark. However, organic dye materials, if used, must be dissolved in organic solvents before applied to a substrate, which results in poor productivity. In addition, the recording signals are insufficient in stability during long-term storage.

To improve these disadvantages of organic dye materials, there has been proposed a technique of carrying out recording of information by using a thin film of, instead of an organic dye material, an inorganic material as a recording layer, and irradiating this thin film with a laser beam to create local recording marks such as holes or pits (see typically to Patent Documents 1 to 7).

Patent Documents 1 and 2 disclose multilayer recording layers each including an assembly of a reactive layer containing a copper-based (Cu-based) alloy containing aluminum (Al), and another reactive layer containing, for example, silicon (Si). These documents mention that a region where atoms contained in the respective reaction layers are mixed is partially formed on the substrate upon irradiation with a laser beam, and reflectivity in that region is greatly changed; therefore, information can be recorded with high sensitivity even if a laser beam having a short wavelength, such as a blue laser beam, is used.

Patent Documents 3 and 4 relate to optical storage media that prevent reduction in carrier to noise ratio (carrier to noise ratio in output level) and exhibit a high carrier to noise ratio and a high reflectivity. The recording layers in these media use a copper-based (Cu-based) alloy containing indium (In) (Patent Document 3) and a silver-based (Ag-based) alloy typically containing bismuth (Bi) (Patent Document 4), respectively.

Patent Documents 5 and 6 relate to optical recording layers using tin (Sn) based alloys. Patent Document 5 discloses an optical information storage medium containing two or more different atoms in a metal alloy layer, which atoms can at least partially aggregate upon heat treatment. Specifically, there is disclosed a tin-copper (Sn—Cu) based alloy layer containing bismuth and/or indium and having a thickness of about 1 to 8 nm. Patent Document 6 discloses a recording layer composed of an alloy of bismuth (Bi) and a low melting metal such as indium (In), tin (Sn), cadmium (Cd), lead (Pb), or zinc (Zn) and further containing nitrogen (N), argon (Ar), and/or sulfur (S), in which the resulting recording marks are free from the risk of erasing. The document mentions that this technique gives an optical recording layer with a high recording sensitivity.

Patent Document 7 relates to an optical storage medium including two-layered recording layer, i.e., a first recording layer composed of an indium alloy containing oxygen, and a second recording layer composed of a selenium (Se) and/or tellurium (Te) alloy containing oxygen. This structure gives an optical recording layer having a high reflectivity and a high recording sensitivity.

Patent Document 1: JP-A No. 2004-5922

Patent Document 2: JP-A No. 2004-234717

Patent Document 3: JP-A No. 2002-172861

Patent Document 4: JP-A No. 2002-144730

Patent Document 5: JP-A No. Hei 02-117887

Patent Document 6: JP-A No. 2002-347340

Patent Document 7: JP-A No. 2003-326848

### DISCLOSURE OF INVENTION

As the demand for high-density information recording grows more and more, there have been developed technologies for recording and reading of information using short-wavelength laser beams such as blue-violet laser beams. Recording layers for use therein should have various characteristic properties such as (1) high-quality writing and reading of signals, such as high carrier to noise ratio (i.e., high (strong) readout signals and low background noise) and low jitter (i.e., less fluctuation of regenerated signals on the time base) and (2) high recording sensitivity (writability of signals with a laser beam at a low power).

Metallic optical recording layers are significantly advantageous in that their materials are furthermore stable than those in organic optical recording layers. It is therefore important to develop practical optical recording layers satisfying the above-mentioned requirements using metallic materials, in order to provide users with highly reliable BD-R and HD DVD-R discs.

Sputtering is desirably employed in deposition of optical recording layers, for high production efficiency. It is therefore desirable to provide sputtering targets for the deposition of high-quality optical recording layers; and optical information storage media provided with the recording layers.

The present invention has been made under these circumstances, and an object of the present invention is to provide a recording layer for an optical information storage medium and an optical information storage medium provided with the recording layer, which recording layer not only satisfies requirements such as the above-mentioned properties (1) and (2), but also can reliably carry out recording of information with good sensitivity. Another object of the present invention is to provide a sputtering target useful for the deposition of the optical information recording layer.

The above objects have been achieved by the present invention. Specifically, there is provided optical information recording layers to create recording marks upon irradiation with a laser beam, which recording layers include: an indium alloy containing 0.1 to 15 atomic percent of one or more rare-earth elements; an indium alloy containing 6 to 50 atomic percent of nickel (Ni); an indium alloy containing 0.1 to 50 atomic percent of one element selected from the group consisting of palladium (Pd), cobalt (Co), platinum (Pt), and vanadium (V); or an indium alloy containing 0.1 to 50 atomic percent (excluding 50 atomic percent) of gold (Au).

The recording layers according to the present invention show a high recording sensitivity and exhibit excellent precision in writing and reading of optical information particularly upon irradiation with a laser beam having a wavelength in the range of 350 to 700 nm.

According to the present invention, there is also provided optical information storage media including any of the optical recording layers of the above configurations. In a preferred embodiment, the optical information storage media further include at least one of an optical control layer and a dielectric layer as an upper layer and/or an underlayer of the recording layer. The thickness of the optical recording layer in the optical information storage medium is preferably in the range of 1 to 50 nm when an optical recording layer and/or a dielectric layer is provided as an upper layer or an underlayer of the optical recording layer; and it is preferably in the range of 8 to 50 nm when neither optical recording layer nor dielectric layer is provided.

According to the present invention, there are also provided targets for use in the deposition of the optical recording layers by sputtering. Specifically, a target according to a first embodiment includes an indium alloy containing 0.1 to 15 atomic percent of one or more rare-earth elements. A target according to another embodiment includes an indium based alloy containing 0.1 to 50 atomic percent of one element selected from the group consisting of palladium (Pd), cobalt (Co), platinum (Pt), and vanadium (V). A target according to yet another embodiment include an indium alloy containing 6 to 50 atomic percent of nickel (Ni), and a target according to still another embodiment includes an indium alloy containing 0.1 to 50 atomic percent (excluding 50 atomic percent) of gold (Au).

In the indium alloys for use in the present invention, indium serving as a base material has a significantly low melting point of 156.6° C. to enable creation of recording marks at a low laser power, as compared to other metals. Indium, however, is likely to have a low carrier to noise ratio and have a rough recording layer with poor surface smoothness due to its low melting point. These disadvantages of indium, however, are improved by adding to indium 0.1 to 15 atomic percent of one or more rare-earth elements; 0.1 to 50 atomic percent of one element selected from the group consisting of palladium (Pd), cobalt (Co), platinum (Pt), and vanadium (V); 6 to 50 atomic percent of nickel (Ni); or 0.1 atomic percent or more and less than 50 atomic percent of gold (Au). The resulting recording layers have satisfactory carrier to noise ratios at practically usable level as optical recording layers, have improved reading waveforms, and are sufficiently practically usable as optical recording layers at a low laser power.

### BRIEF DESCRIPTION OF DRAWINGS

FIG. 1 is a schematic sectional view illustrating optical information storage media according to an embodiment of the present invention.

FIG. 2 is a schematic sectional view illustrating optical information storage media according to another embodiment of the present invention.

FIG. 3 is a schematic sectional view illustrating optical information storage media according to yet another embodiment of the present invention.

FIG. 4 is a schematic sectional view illustrating optical information storage media according to still another embodiment of the present invention.

### REFERENCE NUMERALS

1 substrate
2 optical control layer
3, 5 dielectric layer
4 recording layer
6 light transmission layer
7A, 7B recording layer group
8 intermediate layer
9 adhesive layer
10 optical disc

### BEST MODE FOR CARRYING OUT THE INVENTION

The reasons why indium is selected as the base metal in the present invention are as follows.

When used in an optical recording layer, indium is slightly inferior in reflectivity to other metals such as aluminum (Al), silver (Ag), and copper (Cu), but it is much superior in creativity of recording marks upon irradiation with a laser beam. This is probably because the melting point of indium is about 156.6° C. and is significantly lower than those of aluminum (about 660° C.), silver (about 962° C.), and copper (about 1085° C.); and a thin film of indium alloy readily melts or deforms even at low temperatures upon irradiation with a laser beam to thereby exhibit excellent recording properties even at a low laser power. In addition, when used in a recording layer mainly aiming to be applied to next-generation optical discs using blue-violet laser as in the present invention, an aluminum (Al) based alloy, for example, may fail to create recording marks easily. Thus, indium is selected as the base metal in the present invention.

In indium alloys for use herein, indium basically carries major characteristic properties of the indium alloys as described above. The indium content in the indium alloys is preferably 40 atomic percent or more, more preferably 50 atomic percent or more, and further preferably 60 atomic percent or more.

However, when indium is used alone, the recording layer has a low carrier to noise ratio, has a rough recording layer with poor surface smoothness and lacks practical usability, due to the low melting point of indium. Accordingly, an indium alloy according to a first embodiment of the present invention further contains, in addition to indium, 0.1 to 15 atomic percent, and more preferably 3 to 10 atomic percent, of one or more rare-earth elements. Examples of such rare-earth elements are yttrium (Y), lanthanum (La), neodymium (Nd), gadolinium (Gd), and ytterbium (Yb). An indium alloy according to another embodiment contains 0.1 to 50 atomic percent, and more preferably 10 to 40 atomic percent, of one element selected from the group consisting of palladium (Pd), cobalt (Co), platinum (Pt), and vanadium (V). An indium alloy according to yet another embodiment contains 6 to 50 atomic percent, and more preferably 10 to 40 atomic percent, of nickel (Ni). An indium alloy according to still another embodiment contains 0.1 atomic percent or more and less than 50 atomic percent, and more preferably 10 to 40 atomic percent, of gold (Au). By alloying these alloy elements in suitable amounts, disadvantages of indium, such as low carrier to noise ratio and poor surface smoothness (rough surface) of the recording layer, are improved, while making full use of original characteristic properties of indium. Thus, practically usable recording sensitivity and recording precision are obtained.

Specifically, the rare-earth elements, Pd, Co, Pt, V, Ni, and Au in the indium alloys all act to improve disadvantages of an optical recording layer composed of pure indium, i.e., a large surface roughness and a high noise upon reading of data (i.e., low carrier to noise ratio). To effectively exhibit these activities, the content of rare-earth elements, if used as alloy elements, should be 0.1 atomic percent or more, and is preferably 3 atomic percent or more. On the other hand, by controlling the content of rare-earth elements to 15 atomic percent or less, such a reflectivity in unrecorded portions sufficient to read signals is ensured without reducing the initial reflectivity. Thus, the content of rare-earth elements should be 15 atomic percent or less, and is preferably about 10 atomic percent or less, and more preferably about 8 atomic percent. Examples of the rare-earth elements include yttrium (Y), neodymium (Nd), lanthanum (La), gadolinium (Gd), and ytterbium (Yb). Each of these rare-earth elements can be used alone or in any combination.

In the case of palladium (Pd), cobalt (Co), platinum (Pt), and vanadium (V), the content of each of these elements should be 0.1 atomic percent or more, and is preferably at a content of 10 atomic percent or more, to effectively exhibit the advantageous effects of its addition. On the other hand, by controlling the content of one of palladium (Pd), cobalt (Co), platinum (Pt), and vanadium (V) to 50 atomic percent or less, the relative indium content remains sufficient, to make full use of the original characteristic properties of indium typified by low melting point and to create recording marks satisfactorily. The content of one of palladium (Pd), cobalt (Co), platinum (Pt), and vanadium (V) is more preferably 40 atomic percent or less.

In the case of nickel (Ni), the nickel content should be 6 atomic percent or more and is preferably 10 atomic percent or more, to effectively exhibit the advantageous effects of its addition. On the other hand, by controlling the nickel content to 50 atomic percent or less, the relative indium content remains sufficient, to make full use of the original characteristic properties of indium typified by low melting point and to create recording marks satisfactorily. The nickel content is more preferably 40 atomic percent or less.

In the case of gold, the gold content should be 0.1 atomic percent or more and is preferably 10 atomic percent or more, to effectively exhibit the advantageous effects of its addition. On the other hand, by controlling the gold content to less than 50 atomic percent, the relative indium content remains sufficient, to make full use of the original characteristic properties of indium typified by low melting point and to create recording marks satisfactorily. The gold content is more preferably 40 atomic percent or less.

Optical recording layers of the indium alloys preferably have a thickness in the range of 1 to 50 nm so as to act as recording layers capable of reliably recording data with a stable precision, while such preferred thickness may vary depending on the structure of the optical information storage media. An optical recording layer having a not excessively small thickness of 1 nm or more is resistant to defects such as pores on its surface and thereby provides a satisfactory recording sensitivity, even when neither optical control layer nor dielectric layer is arranged as an upper layer and/or an underlayer of the optical recording layer. In contrast, an optical recording layer having a not excessively large thickness of 50 nm or less creates satisfactory recording marks, because heat generated by the application of laser beams is inhibited from diffusing in the recording layer. The thickness of the recording layers is more preferably 8 nm or more and 50 nm or less, and further preferably 10 nm or more and 25 nm or less when neither dielectric layer nor optical control layer is arranged. The thickness is more preferably 3 nm or more and 30 nm or less, and further preferably 5 nm or more and 25 nm or less when at least one of a dielectric layer and an optical control layer is arranged.

A laser beam to be applied for the recording of information preferably has a wavelength in the range of 350 to 700 nm. A laser beam having a wavelength of 350 nm or more is resistant to absorption by a covering layer such as a light transmission layer, whereby the writing to and reading from the optical recording layer can be satisfactorily conducted. On the other hand, a laser beam having a wavelength of 700 nm or less has sufficient energy, to thereby create recording marks on the optical recording layer satisfactorily. From these viewpoints, a laser beam for use in information recording may have a wavelength of more preferably 350 nm or more and 660 nm or less, and further preferably 380 nm or more and 650 nm or less.

Sputtering targets for the deposition of the optical recording layers according to the present invention have compositions basically the same as the alloy compositions of the optical recording layers. In other words, optical recording layers having desired alloy compositions can be easily deposited through sputtering by adjusting the compositions of sputtering targets to the alloy compositions mentioned as indium alloys.

Advantages of the present invention will be illustrated below in contrast with the known techniques (above-mentioned Patent Documents 1 to 7).

Indium used in the present invention is somewhat inferior in reflectivity to aluminum (Al), silver (Ag), and copper (Cu) disclosed in JP-A No. 2004-5922, JP-A No. 2004-234717, JP-A No. 2002-172861, and JP-A No. 2002-144730. Indium is, however, significantly superior in creation of recording marks upon irradiation with a laser beam to these metals. This is probably because, as is described above, the melting point of indium is about 156.6° C. and is significantly lower than those of aluminum (about 660° C.), silver (about 962° C.), and copper (about 1085° C.); and a very thin film of indium alloy readily melts or deforms at low temperatures upon irradiation with a laser beam to thereby exhibit excellent recording properties even at a low laser power.

In addition, when applied to next-generation optical discs using blue-violet laser as in the present invention, an aluminum thin film, for example, as a recording layer may fail to create recording marks at a low laser power.

JP-A No. Hei 2-117887 discloses an optical recording layer including an alloy of 40 percent by mass of tin (Sn), 55 percent by mass of indium (In), and 5 percent by mass of copper (Cu) and having a film thickness of 2 to 4 nm. This alloy contains, in terms of atomic percent, 37.7 atomic percent of tin, 53.5 atomic percent of indium, and 8.8 atomic percent of copper. This optical recording layer, however, failed to yield a practically sufficient carrier to noise ratio. The alloy layer disclosed in this patent document has a thickness of 2 to 4 nm. This thickness, however, is too small for the alloy composition to yield a practically sufficient reflectivity, as verified by experiments.

The optical recording layer disclosed in JP-ANo. 2002-347340 which contains bismuth (Bi) and a low melting metal such as indium (In), tin (Sn), cadmium (Cd), lead (Pb), or zinc (Zn) alone has large surface roughness and a large media noise to fail to provide a practically sufficient carrier to noise ratio.

JP-A No. 2003-326848 discloses an optical recording layer including a first layer of an indium alloy and a second layer of a selenium (Se) and/or tellurium (Te) alloy. This alloy system uses harmful metals such as selenium and tellurium and there is a problem with respect to the safety of the alloy.

These also demonstrate that optical recording layers according to the present invention are more useful than known equivalents.

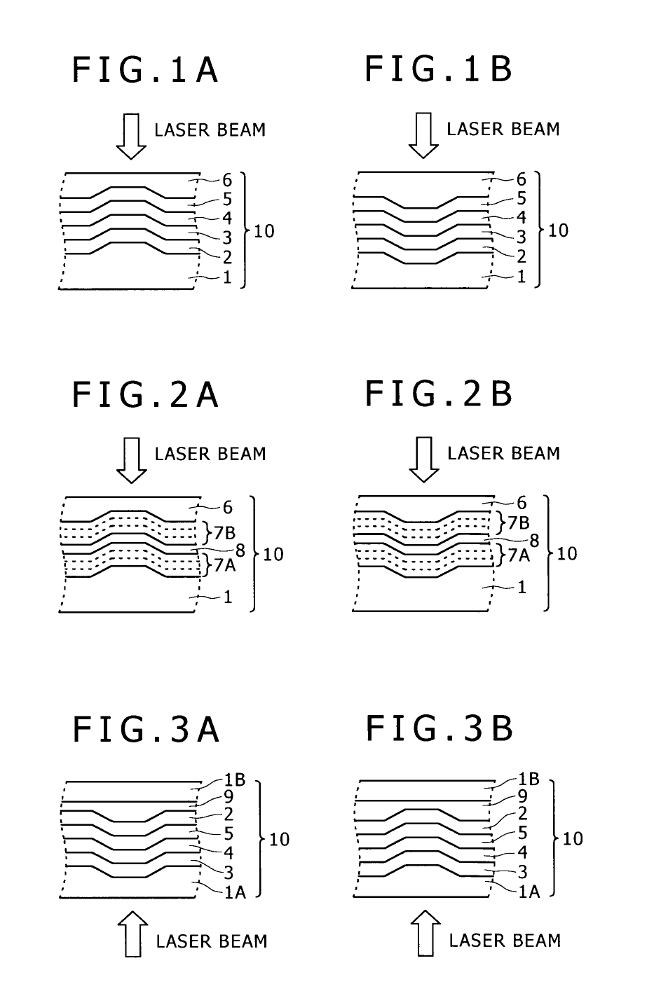

FIGS. 1 to 4 are schematic sectional views showing embodiments of optical information storage media (optical discs) according to the present invention. These are write-once optical discs configured to write and read data by applying a laser beam with a wavelength of 350 to 700 nm to a recording layer. The optical discs shown in FIGS. 1(A), 2(A), 3(A), 4(A), and 4(C) each have a convex recording site, and those shown in 1(B), 2(B), 3(B), 4(B), and 4 (D) each have a concave recording site, when seen from the direction of incident laser beam.

Each of optical discs 10 in FIG. 1 includes a substrate 1, an optical control layer 2, dielectric layers 3 and 5, a recording layer 4 disposed between the dielectric layers 3 and 5, and a light transmission layer 6. The dielectric layers 3 and 5 are provided to protect the recording layer 4, thereby allowing long-term storage of recorded information.

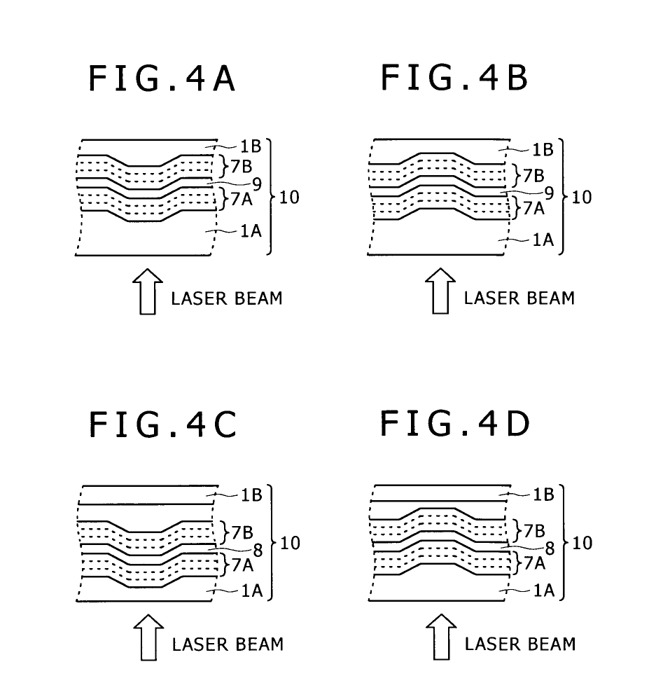

Each of optical discs 10 in FIG. 2 includes a substrate 1, a zeroth recording layer group (a group of layers including an optical control layer, a dielectric layer, and a recording layer) 7A, an intermediate layer 8, a first recording layer group (a group of layers including an optical control layer, a dielectric layer, and a recording layer) 7B, and a light transmission layer 6. FIG. 3 illustrates optical discs of a single-layer DVD-R, a single-layer DVD+R, or a single-layer HD DVD-R type. FIG. 4 illustrates optical discs of a double-layer DVD-R, a double-layer DVD+R, or a double-layer HD DVD-R type. The numeral 8 stands for an intermediate layer, and the numeral 9 stands for an adhesive layer.

A group of layers constituting the zeroth and first recording layer groups 7A and 7B in FIGS. 2 and 4 may have a three-layer structure, a two-layer structure, or a single-layer structure including a recording layer alone. The three-layer structure may be a structure of, for example, (dielectric layer)/(recording layer)/(dielectric layer), (dielectric layer)/(recording layer)/(optical control layer), or (recording layer)/(dielectric layer)/(optical control layer) arranged in this order from above in the figures. The two-layer structure may be a structure of, for example, (recording layer)/(dielectric layer), (dielectric layer)/(recording layer), (recording layer)/(optical control layer), or (optical control layer)/(recording layer) arranged in this order from above in the figures.

Optical discs as representative embodiments of the present invention have a feature of employing indium alloys satisfying the above requirements as a material for the recording layer 4 as shown in FIGS. 1 to 4. Materials for the substrate 1, the optical control layer 2, the dielectric layers 3 and 5, and other components than the recording layer 4 are not particularly limited and can be selected as appropriate from among generally used materials.

Specifically, materials for the substrate include polycarbonate resins, norbornene resins, cyclic olefin copolymers, and amorphous polyolefins; materials for the optical control layer include metals such as Ag, Au, Cu, Al, Ni, Cr, and Ti, and alloys of these metals; materials for the dielectric layer include ZnS—SiO₂, oxides typically of Si, Al, Ti, Ta, Zr, and Cr, nitrides typically of Ge, Cr, Si, Al, Nb, Mo, Ti, and Zn, carbides typically of Ge, Cr, Si, Al, Ti, Zr, and Ta, fluorides typically of Si, Al, Mg, Ca, and La, and mixtures of these materials.

As is described above, at least one of an optical control layer and a dielectric layer is preferably arranged to increase the reflectivity as a disc. In this case, the thickness of the recording layer is preferably 1 to 50 nm, more preferably 3 to 30 nm, and further preferably 5 to 20 nm.

When optical discs employ any of the optical recording layers having the above specified configurations, part or all of the optical control layer 2 and the dielectric layers 3 and 5 can be omitted. The thickness of the optical recording layer, if used as a single layer, is preferably 8 to 50 nm, and more preferably 10 to 25 nm.

The optical recording layers of indium alloys are preferably deposited by sputtering. Specifically, the alloy elements (rare-earth elements, Pd, Co, Pt, V, Ni, and Au) for use herein in addition to indium have specific solubility limits with respect to indium in thermal equilibrium. However, the alloy elements in a thin film, if deposited by sputtering, are more uniformly distributed in the indium matrix, and the resulting thin film has homogenous properties and is likely to have more stable optical properties and environmental resistance.

Targets for use in sputtering are preferably composed of an indium-based alloy prepared by melting and casting (hereinafter also referred to as “ingot indium-based alloy target”). This is because such an ingot indium-based alloy target has a uniform texture and composition, shows a stable sputtering rate, and emits atoms at uniform angles. Thus, the target contributes to the deposition of an optical recording layer having a homogenous alloy composition, and this in turn contributes to the production of an optical disc being homogenous and having high performance.

During the preparation of a target typically by vacuum melting, trace amounts of impurities such as nitrogen, oxygen, and other gaseous components in atmosphere, and components of a melting furnace may contaminate the target. The component compositions of optical recording layers and targets according to the present invention do not define these inevitable trace components (impurities). Trace amounts of such inevitable impurities are acceptable, as long as they do not adversely affect the characteristic properties obtained according to embodiments of the present invention.

### EXAMPLES

The present invention will be illustrated in further detail with reference to examples below. It should be noted, however, the following examples are never intended to limit the scope of the present invention, and appropriate modifications and variations without departing from the spirit and scope of the present invention set forth above and below fall within the technological scope of the present invention.

### Example 1

### 1) Preparation of Discs

Optical recording layers were deposited by DC magnetron sputtering using, as disc substrates, two types of polycarbonate substrates, i.e., a BD substrate having a thickness of 1.1 mm, a track pitch of 0.32 μm, a groove width of 0.14 to 0.16 μm, and a groove depth of 25 nm; and a grooveless substrate having a thickness of 0.6 mm. For the sake of simplicity, there were used, as sputtering targets, composited targets each including a 4-inch indium target with chips (5-n square or 10-mm square) of an alloy element arranged on the indium target.

The sputtering for the deposition of optical recording layers was conducted under conditions of a base pressure of 10⁻⁶ Torr or less (1 Torr equals 133.3 Pa), an argon (Ar) gas pressure of 4 mTorr, and a DC sputtering power of 50 W. The thicknesses of the recording layers were varied by changing the sputtering duration in the range of 5 sec to 30 sec. The compositions of the deposited indium alloy layers were determined by inductively coupled plasma (ICP) emission spectrometry and inductively coupled plasma (ICP)-mass spectrometry.

### 2) Evaluation Methods of Optical Discs

The initial reflectivity, surface roughness, and creativity of recording marks were evaluated using thin film samples deposited each on a grooveless substrate having a thickness of 0.6 mm. Specifically, the initial reflectivity was measured with a spectrophotometer (supplied from JASCO Corporation under the trade name of “V-570”) by applying a laser beam having a wavelength of 405 nm to the respective optical recording layers. The surface roughness (Ra; in unit of nanometer) of the optical recording layers was measured in a measuring area of 2.5 μm long and 2.5 μm wide with an atomic force microscope (supplied by Seiko Instruments Inc. under the trade name of “SPI 4000” Probe Station) in AFM mode.

As the creativity of recording marks, a laser power at which good recording marks were created on a sample recording layer was determined at a beam speed of 5 m/s using the “POP 120-8R” (trade name; supplied from Hitachi Computer Peripherals Co., Ltd.). The laser beam was applied from the side of the recording layer using semiconductor laser having a wavelength of 405 nm as a light source at a laser spot size of 0.8 μm in diameter. The recorded mark was observed under an optical microscope, and the ratio of the area of the mark to the area of irradiated laser beam was determined by image processing analysis and calculation. A sample having an area ratio of 85% or more was accepted herein.

For the media noise, samples were prepared by depositing recording layers each on a grooved substrate 1.1 mm thick, and applying a cover layer 0.1 nm thick thereon, followed by curing. The media noise was measured on the samples at a beam speed of 5.28 m/s and a frequency of 16.5 MHz with an optical disc evaluation system (supplied by Pulstec Industrial Co., Ltd. under the trade name of “ODU-1000”; recording laser wavelength: 405 nm, numerical aperture (NA): 0.85) and a spectrum analyzer (supplied by Advantest Corporation under the trade name of “R3131A”). The media noise was measured on unrecorded samples.

The results are together shown in Table 1. The symbols in Table 1 mean as follows.

(1) Initial Reflectivity

A: 30% or more, B: 25% or more and less than 30%, C: 20% or more and less than 25%, D: less than 20%

(2) Creativity of Recording Marks

A: 15 mW or less, B: more than 15 mW and 25 mW or less, C: more than 25 mW

(3) Surface Roughness (Ra)

A: 2.0 nm or less, B: more than 2.0 nm and 4.0 nm or less, C: more than 4.0 nm

(4) Media Noise

A: −75 dB or less, B: more than −75 dB and −65 dB or less, C: more than −65 dB

TABLE 1

| | | Layer | | Creativity of | Surface | |
|---|---|---|---|---|---|---|
| Sample | Alloy composition | thickness | Initial | recording | roughness | Media |
| Number | (atomic percent) | (nm) | reflectivity | marks | (Ra) | noise |
| 1 | In | 25.0 | A | A | C | C |
| 2 | In—0.05% Y | 25.0 | A | A | C | C |
| 3 | In—0.1% Y | 25.0 | A | A | B | B |
| 4 | In—6% Y | 1.0 | C | A | A | A |
| 5 | In—6% Y | 3.0 | C | A | A | A |
| 6 | In—6% Y | 5.0 | B | A | A | A |
| 7 | In—6% Y | 15.0 | B | A | A | A |
| 8 | In—6% Y | 25.0 | B | A | A | A |
| 9 | In—6% Y | 50.0 | A | B | B | B |
| 10 | In—6% Y | 55.0 | A | C | B | B |
| 11 | In—15% Y | 25.0 | B | B | A | A |
| 12 | In—16% Y | 25.0 | D | B | A | A |
| 13 | In—3% Nd | 25.0 | B | A | A | A |
| 14 | In—9% Nd | 25.0 | B | A | A | A |
| 15 | In—7% La | 25.0 | B | A | A | A |
| 16 | In—10% La | 25.0 | B | A | A | A |
| 17 | In—4% Yb | 25.0 | B | A | A | A |
| 18 | In—8% Gd | 25.0 | B | A | A | A |
| 19 | In—3% Y—3% Nd | 25.0 | B | A | A | A |
| 20 | In—4% Ni | 25.0 | A | A | C | C |
| 21 | In—6% Ni | 25.0 | A | A | B | B |
| 22 | In—10% Ni | 25.0 | A | A | A | A |
| 23 | In—20% Ni | 1.0 | C | A | A | A |
| 24 | In—20% Ni | 5.0 | B | A | A | A |
| 25 | In—20% Ni | 10.0 | A | A | A | A |
| 26 | In—20% Ni | 25.0 | A | A | A | A |
| 27 | In—20% Ni | 50.0 | A | B | A | A |
| 28 | In—20% Ni | 55.0 | A | C | A | A |
| 29 | In—40% Ni | 25.0 | A | A | A | A |
| 30 | In—50% Ni | 25.0 | A | B | A | A |
| 31 | In—55% Ni | 25.0 | A | C | A | A |

TABLE 2

| | | Layer | | Creativity of | Surface | |
|---|---|---|---|---|---|---|
| Sample | Alloy composition | thickness | Initial | recording | roughness | Media |
| Number | (atomic percent) | (nm) | reflectivity | marks | (Ra) | noise |
| 1 | In | 25.0 | A | A | C | C |
| 32 | In—0.05% Pd | 25.0 | A | A | C | C |
| 33 | In—0.1% Pd | 25.0 | A | A | B | B |
| 34 | In—20% Pd | 25.0 | A | A | A | A |
| 35 | In—40% Pd | 25.0 | A | A | A | A |
| 36 | In—50% Pd | 25.0 | A | B | A | A |
| 37 | In—55% Pd | 25.0 | A | C | A | A |
| 38 | In—10% Co | 25.0 | A | A | A | A |
| 39 | In—20% Co | 25.0 | A | A | A | A |
| 40 | In—50% Co | 25.0 | A | B | A | A |
| 41 | In—55% Co | 25.0 | A | C | A | A |
| 42 | In—30% Pt | 25.0 | A | A | A | A |
| 43 | In—40% Pt | 25.0 | A | A | A | A |
| 44 | In—50% Pt | 25.0 | A | B | A | A |
| 45 | In—55% Pt | 25.0 | A | C | A | A |
| 46 | In—0.05% Au | 25.0 | A | A | C | C |
| 47 | In—20% Au | 10.0 | A | A | A | A |
| 48 | In—20% Au | 20.0 | A | A | A | A |
| 49 | In—20% Au | 25.0 | A | A | A | A |
| 50 | In—30% Au | 25.0 | A | A | A | A |
| 51 | In—40% Au | 25.0 | A | B | A | A |
| 52 | In—48% Au | 25.0 | A | B | A | A |
| 53 | In—50% Au | 25.0 | A | C | A | A |
| 54 | In—10% V | 15.0 | A | A | A | A |
| 55 | In—10% V | 25.0 | A | A | B | B |
| 56 | In—20% V | 25.0 | A | A | B | B |
| 57 | In—50% V | 25.0 | A | B | B | B |
| 58 | In—55% V | 25.0 | A | C | B | B |

Tables 1 and 2 demonstrate that samples as examples satisfying all requirements in the present invention (Samples Nos. 3, 6 to 9, 11, 13 to 19, 21, 22, 24 to 27, 29, 30, 33 to 36, 38 to 40, 42 to 44, 47 to 52, and 54 to 57) are each good in initial reflectivity, do not require an excessively large laser power to create recording marks, and are good in surface roughness and media noise. In contrast, the sample of pure indium (No. 1) is inferior in surface roughness and media noise and is not practically usable. Samples as comparative examples containing alloy elements in insufficient amounts (Nos. 2, 20, 32, and 46) are also inferior in surface roughness and media noise. On the other hand, samples as comparative examples containing alloy elements in excessively large amounts (Nos. 31, 37, 41, 45, 53, and 58) contain relatively insufficient amounts of indium, and are thereby poor in creativity of recording marks. Sample No. 12 is a comparative example containing an excessively large amount of a rare-earth element and is inferior in initial reflectivity.

Samples Nos. 10 and 28 are referential examples having appropriate indium alloy compositions but having excessively large layer thicknesses. These samples show excessively large absorption with respect to the laser power to show inferior creativity of recording marks. In contrast, Samples Nos. 4, 5, and 23 are referential examples having somewhat relatively small layer thicknesses and have somewhat insufficient initial reflectivity.

While the present invention has been described in detail with reference to specific embodiments, it is obvious to those skilled in the art that various alternations and modifications are possible within the spirit and scope of the present invention.

This application is based on a Japanese Patent Application filed on Feb. 3, 2006 (Japanese Patent Application No. 2006-027192) and a Japanese Patent Application filed on Jun. 13, 2006 (Japanese Patent Application No. 2006-163846), the entire contents of which are incorporated herein by reference.

### INDUSTRIAL APPLICABILITY

In the indium alloys for use in the present invention, indium serving as a base material has a significantly low melting point of 156.6° C. to enable creation of recording marks at a low laser power, as compared to other metals. Indium, however, is likely to have a low carrier to noise ratio and have a rough recording layer with poor surface smoothness due to its low melting point. These disadvantages of indium, however, are improved by adding to indium 0.1 to 15 atomic percent of one or more rare-earth elements; 0.1 to 50 atomic percent of one element selected from the group consisting of palladium (Pd), cobalt (Co), platinum (Pt), and vanadium (V); 6 to 50 atomic percent of nickel (Ni); or 0.1 atomic percent or more and less than 50 atomic percent of gold (Au). The resulting recording layers have satisfactory carrier to noise ratios at practically usable level as optical recording layers, have improved reading waveforms, and are sufficiently practically usable as optical recording layers at a low laser power.

1-14. (canceled)

15. A recording layer for an optical information storage medium to create recording marks upon irradiation with a laser beam,
the recording layer comprising an indium alloy wherein the alloying component is selected from the group consisting of:
(a) 0.1 to 15 atomic percent of one or more rare-earth elements;
(b) 0.1 to 50 atomic percent of one element selected from the group consisting of palladium (Pd), cobalt (Co), platinum (Pt), and vanadium (V);
(c) 6 to 50 atomic percent of nickel (Ni); and
(d) 0.1 atomic percent or more and less than 50 atomic percent of gold (Au).

16. The recording layer according to claim 15, wherein the laser beam has a wavelength in the range of 350 to 700 nm.

17. The recording layer according to claim 15, wherein the indium alloy contains 40 atomic percent or more of indium.

18. An optical information storage medium comprising the recording layer of claim 15.

19. The optical information storage medium according to claim 18, further comprising at least one of an optical control layer and a dielectric layer as an upper layer and/or an underlayer of the recording layer.

20. The optical information storage medium according to claim 18, wherein the recording layer has a thickness of 1 to 50 nm.

21. The optical information storage medium according to claim 19, wherein the recording layer has a thickness of 1 to 50 nm.

22. A sputtering target for the deposition of a recording layer of an optical information storage medium, the sputtering target comprising an indium alloy wherein the alloying component is selected from the group consisting of:
(a) 0.1 to 15 atomic percent of one or more rare-earth elements;
(b) 0.1 to 50 atomic percent of one element selected from the group consisting of palladium (Pd), cobalt (Co), platinum (Pt), and vanadium (V);
(c) 6 to 50 atomic percent of nickel (Ni); and
(d) 0.1 atomic percent or more and less than 50 atomic percent of gold (Au).
